(19) United States
(12) Patent Application Publication
(10) Pub. No.: US 2026/0199994 A1
(43) Pub. Date: Jul. 16, 2026

(54) SURFACE TREATMENT METHOD AND SURFACE TREATMENT DEVICE

(71) Applicant: YASUNAGA CORPORATION, Mie (JP)

(72) Inventors: Yosuke KIRYU, Iga City, Mie (JP); Yasuhiro TAWA, Kawagoe-shi, Saitama (JP); Tomohisa KATOU, Tsukuba-shiIbaraki (JP)

(73) Assignee: YASUNAGA CORPORATION, Mie (JP)

(21) Appl. No.: 19/137,584

(22) PCT Filed: Dec. 14, 2023
(86) PCT No.: PCT/JP2023/044853

§ 371 Date: Jun. 10, 2025

(30) Foreign Application Priority Data
Dec. 16, 2022 (JP) 2022-201432

(51) Int. Cl. B23H 1/04; H10P 52/00

(52) U.S. Cl. CPC B23H 1/04; H10P 52/00

(57) ABSTRACT

A machining electrode (30) having a circular shape in plan view and an outer diameter equal to or larger than an outer diameter of a workpiece is positioned above the workpiece so that the machining electrode (30) partially overlaps the workpiece in plan view. The workpiece is rotated about a first central axis (X1); the machining electrode (30) is rotated about a second central axis (X2); and discharge is caused between the machining electrode (30) and the workpiece with both the workpiece and the machining electrode (30) being rotated.

### TECHNICAL FIELD

The technology disclosed herein belongs to a technical field related to a surface treatment method and a surface treatment device.

### BACKGROUND ART

Techniques of machining a surface of a disc-shaped conductive workpiece into a desired shape or modifying the state of the surface have been known. For example, when the workpiece is a semiconductor wafer, a surface of the wafer is flattened or formed into a convex shape in accordance with the manufacturing conditions of semiconductor chips. When the workpiece is a SiC seed crystal, a surface of the crystal to be bonded with a mount may be modified for better adhesion between the seed crystal and the mount.

Patent Document 1 discloses a method of physically polishing a surface of a semiconductor wafer using polishing slurry.

Patent Document 2 discloses a method of flattening a surface of a wafer blank by discharging electricity on the surface of the wafer blank from a machining electrode placed to cover the entire wafer blank.

Patent Document 3 discloses a method of electrical discharge machining of a surface of a disc-shaped SiC seed crystal to form a modified layer and bonding the modified layer to a mount with an adhesive.

### CITATION LIST

### Patent Documents

Patent Document 1: Japanese Unexamined Patent Publication No. 2009-81186
Patent Document 2: Japanese Unexamined Patent Publication No. 2012-236241
Patent Document 3: Japanese Unexamined Patent Publication No. 2015-30659

### SUMMARY OF THE INVENTION

### Technical Problem

In the case of using the polishing slurry to polish the surface as described in Patent Document 1, the polishing slurry needs to be constantly checked for uneven distribution on the surface of the workpiece, and the machining efficiency is not necessarily high. The method of machining the workpiece in a contact manner, such as the method using the polishing slurry, requires upsizing of a device for higher rigidity when the workpiece is made of a material having high hardness, such as SiC.

In contrast, when the surface of the workpiece is machined by electrical discharge machining as described in Patent Document 2, the machining can be performed without bringing the workpiece and the electrode into contact. This reduces a management load during the machining and the increase of the device size as well. However, if the workpiece is entirely covered with the machining electrode as described in Patent Document 2, electrical discharge is concentrated on portions of the surface where electric charges tend to concentrate, such as an edge portion of the entire surface of the workpiece, making it difficult to machine the surface of the workpiece into a desired shape. If the machining electrode is worn unevenly as a result of the concentrated discharge, the uneven surface shape of the machining electrode causes irregular discharge, and the machining into a desired shape becomes more difficult.

In Patent Document 3, although the roughness of the bonding surface is mentioned, a machining device for obtaining a desired roughness is not disclosed in detail.

To solve the above problems, the technique disclosed herein has been made to reduce unintended machining irregularities on a surface of a disc-shaped workpiece subjected to electrical discharge machining.

### Solution to the Problem

As a solution to the problems, the technique disclosed herein is directed to a surface treatment method for performing electrical discharge machining on a surface of a disc-shaped workpiece using a machining electrode. The machining electrode has a circular shape in plan view and an outer diameter equal to or larger than an outer diameter of the workpiece. The surface treatment method includes: positioning the machining electrode above the workpiece so that the workpiece and the machining electrode partially overlap each other in plan view; rotating the workpiece about a central axis of the workpiece; rotating the machining electrode about a central axis of the machining electrode; and discharging between the machining electrode and the workpiece, with both the workpiece and the machining electrode being rotated. In this configuration, the workpiece and the machining electrode partially overlap each other, limiting a discharge region. The workpiece is rotated about the central axis, and thus, every part of the surface of the workpiece comes directly below the machining electrode at least once. This allows the electrical discharge machining of the entire surface of the workpiece while limiting the discharge region, reducing locally concentrated machining due to the surface state of the workpiece.

The machining electrode itself is also rotated about a cylinder axis, sequentially changing part of the machining electrode that faces the workpiece and causes electrical discharge. This can reduce the progress of local wear of the machining electrode, and can reduce machining irregularities due to wear conditions of the machining electrode.

According to the surface treatment method, the machining electrode may have a cylindrical shape that is open toward the workpiece.

This configuration allows the electrical discharge machining on the surface of the workpiece with the discharge region further limited. With the workpiece being rotated, the entire surface of the workpiece can be machined although the machining electrode is cylindrical. This can reduce the influence of the surface state of the workpiece more effectively, and can reduce unintended machining irregularities more effectively.

According to one embodiment of the surface treatment method, the method further includes moving at least one of the workpiece or the machining electrode in a horizontal direction during the discharging.

That is, for flattening the surface of the workpiece, it is desirable to perform the electrical discharge machining evenly on the entire workpiece. If the relative positions of the workpiece and the machining electrode are fixed, time taken to machine a center portion and a peripheral portion of the workpiece may vary. By moving at least one of the workpiece or the machining electrode in the horizontal direction, it is possible to move the machining electrode away from the center portion of the workpiece and make only the peripheral portion of the workpiece subjected to the electrical discharge machining. This can minimize the variations in machining time between the center portion and the peripheral portion of the workpiece. As a result, a flat surface is easily obtained.

If the surface of the workpiece needs to be formed into a so-called convex shape having the peripheral portion thinner than the center portion, the discharge needs to be performed on the peripheral portion for as long as possible. In this case, only the peripheral portion of the workpiece is allowed to overlap the machining electrode so that the electrical discharge machining continues only on the peripheral portion of the workpiece. A convex surface can thus be obtained.

This can reduce unintended machining irregularities on one hand, while allowing intentionally localized machining according to the desired surface shape on the other.

Further, the surface of the machining electrode opposed to the workpiece can face any part of the surface of the workpiece, allowing the machining electrode to be worn more evenly.

According to the embodiment, the machining electrode may have a cylindrical shape that is open toward the workpiece, and the moving may include moving the at least one of the workpiece or the machining electrode in the horizontal direction in a range where a distance L between the central axis of the workpiece and the central axis of the machining electrode meets

$$R - d < L < r + R$$

where r represents a radius of the surface of the workpiece, R represents an outer radius of the machining electrode, and d represents a width of a cylindrical portion of the machining electrode (d<r).

That is, the entire workpiece can be machined by changing the relative positions of the workpiece and the machining electrode within the above range. In other words, a region where the workpiece and the machining electrode overlap each other can be more limited, allowing suitable machining of the entire workpiece. This can reduce the influence of the surface state of the workpiece and the locally concentrated wear of the machining electrode more effectively. As a result, unintended machining irregularities can be reduced more effectively.

According to the embodiment in which the horizontal movement is allowed within the limited range, a direction of rotation of the workpiece during the rotating and a direction of rotation of the machining electrode during the rotating may be the same.

Thus, in the region where the workpiece and the machining electrode overlap each other, the moving directions of the machining electrode and the workpiece can be different. This can reduce variations in machining time more effectively, and can reduce unintended machining irregularities more effectively.

According to the embodiment in which the workpiece and the machining electrode rotate in the same direction, a number of rotations of the machining electrode during the rotating may not be an integer multiple of a number of rotations of the workpiece during the rotating.

If the number of rotations of the machining electrode is an integer multiple of the number of rotations of the workpiece, the machining electrode regularly faces a certain part of the workpiece, and machining irregularities may occur. If the number of rotations of the machining electrode is controlled not to be an integer multiple of the number of rotations of the workpiece, the machining electrode faces different parts of the workpiece at random, reducing unintended machining irregularities more effectively.

The technique disclosed herein is also directed to a surface treatment device configured to perform electrical discharge machining on a surface of a disc-shaped workpiece. Specifically, the surface treatment device includes: a table on which the workpiece is placed and held; a machining electrode having a circular shape in plan view and an outer diameter equal to or larger than an outer diameter of the workpiece; a first rotator configured to rotate the workpiece about a central axis of the workpiece; a second rotator configured to rotate the machining electrode about a central axis of the machining electrode; and a controller electrically connected to the machining electrode, the first rotator, and the second rotator. The controller causes the first rotator to rotate the workpiece and causes the second rotator to rotate the machining electrode, with the workpiece and the machining electrode partially overlapping each other in plan view to perform the electrical discharge machining.

This configuration allows the electrical discharge machining of the entire surface of the workpiece while limiting the discharge region, reducing locally concentrated machining due to the surface state of the workpiece. The machining electrode itself is also rotated about the cylinder axis, reducing the progress of local wear of the machining electrode. For these reasons, the unintended machining irregularities can be reduced.

According to the surface treatment device described above, the machining electrode may have a cylindrical shape that is open toward the workpiece.

This configuration allows the electrical discharge machining on the surface of the workpiece with the discharge region further limited. With the workpiece being rotated, the entire surface of the workpiece can be machined although the machining electrode is cylindrical. This can reduce the influence of the surface state of the workpiece more effectively, and can reduce unintended machining irregularities more effectively.

According to the surface treatment device, at least one of the table or the machining electrode may be configured to be movable in a horizontal direction, and the controller may be configured to be able to perform the electrical discharge machining while moving at least one of the table or the machining electrode in the horizontal direction.

This configuration can also control time for machining the center portion and the peripheral portion of the workpiece according to a desired surface shape. Further, the surface of the machining electrode opposed to the workpiece can face any part of the surface of the workpiece. This can reduce unintended machining irregularities on one hand, while allowing intentionally localized machining according to the desired surface shape on the other.

According to the surface treatment device, the controller may control the first rotator and the second rotator so that a number of rotations of the machining electrode is not an integer multiple of a number of rotations of the workpiece.

If the number of rotations of the machining electrode is controlled not to be an integer multiple of the number of rotations of the workpiece, the machining electrode faces different parts of the workpiece at random, reducing unintended machining irregularities more effectively.

### Advantages of the Invention

As described above, the technique disclosed herein can more effectively reduce unintended machining irregularities on the workpiece subjected to electrical discharge machining.

### BRIEF DESCRIPTION OF THE DRAWINGS

FIG. 1 is a simplified diagram of a surface treatment device according to a first embodiment.

FIG. 2 is a diagram for explaining the positional relationship between a wafer and a machining electrode.

FIG. 3 is an operation diagram of the surface treatment device, showing a wafer fixed to a mount table.

FIG. 4 is an operation diagram of the surface treatment device, showing the machining electrode moved to a predetermined position from the position shown in FIG. 3.

FIG. 5 is an operation diagram of the surface treatment device, showing the machining electrode lowered from the position shown in FIG. 4 to start the surface treatment.

FIG. 6 is an operation diagram of the surface treatment device, showing the machining electrode horizontally moved in the radial direction of the wafer from the position shown in FIG. 5.

FIG. 7 is an operation diagram of the surface treatment device on completion of the surface treatment.

FIG. 8 is a schematic diagram illustrating the arrangement of the machining electrode when machining only a specific part of a wafer by the surface treatment device.

FIG. 9 is a cross-sectional view of a SiC seed crystal subjected to electrical discharge machining by the surface treatment device.

FIG. 10 is a simplified diagram of a surface treatment device according to a second embodiment.

FIG. 11 is an operation diagram of the surface treatment device according to the second embodiment.

### DESCRIPTION OF EMBODIMENTS

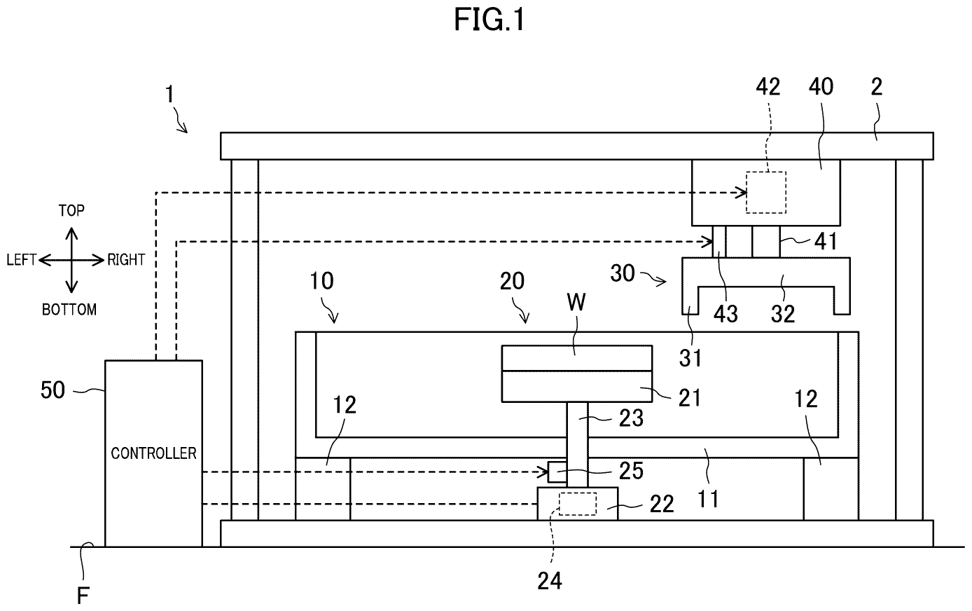

Exemplary embodiments will be described in detail below with reference to the drawings. Note that the top, the bottom, the left, and the right used in the following description are based on the arrows shown in FIG. 1. The directions used herein do not limit the arrangement of a surface treatment device 1 in an actual use. In this specification, the term “surface treatment” does not merely include the machining of a surface shape, but also includes treatments for changing surface properties.

### First Embodiment

FIG. 1 schematically shows a surface treatment device 1 according to a first embodiment. The surface treatment device 1 is a device for treating a surface of a workpiece, which is a conductive wafer W, particularly a semiconductor wafer, into a desired shape by electrical discharge machining. The wafer W used as the workpiece includes various wafers, such as those of Si, Ge, SiC, GaAs, GaP, InP, GaN, and AlN. The wafer W may be a wafer sliced from an ingot with a wire saw, or may be a wafer grown into a single wafer. The workpiece is not limited to the wafer, and may be any object having a circular surface. For example, the workpiece may be disc-shaped SiC or GaN having a thickness ranging from 1 mm to 10 mm.

The surface treatment device 1 includes a box-shaped housing 2 placed on a floor surface F. The housing 2 houses a treatment tank 10 that stores a treatment fluid, a table 20 on which the wafer W is placed and held, and a machining electrode 30 that causes electrical discharge between the machining electrode 30 and the wafer W.

The treatment tank 10 includes a tank body 11 that stores the treatment fluid and a plurality of legs 12 that support the tank body 11. The treatment fluid stored in the tank body 11 is water or oil. The treatment fluid is used to remove debris generated by the electrical discharge machining from the wafer W and cool the wafer W during the electrical discharge machining. The treatment tank 10 may be provided with a flow generator for causing flow of the treatment fluid.

The table 20 includes a mount 21 on which the wafer W is placed, a base 22 arranged on a lower surface of the housing 2, and a column 23 that connects the mount 21 and the base 22 in the up-down direction. As shown in FIG. 1, the mount 21 is located inside the tank body 11, and the base 22 is located below the bottom of the tank body 11. The column 23 extends to penetrate the bottom of the tank body 11. When the wafer W is placed on the mount 21, the wafer W is immersed in the treatment fluid. Although not shown, a sealing mechanism is provided between the column 23 and the bottom of the tank body 11 to prevent the treatment fluid from leaking.

The wafer W placed on the table 20 is held not to move from the mount 21. In particular, the wafer W is held on the mount 21 so that the wafer W rotates together with the mount 21 when the mount 21 rotates as described later. Various methods can be used to hold the wafer W on the mount 21. For example, the wafer W can be held by vacuum suction, with a conductive adhesive, or with an adhesive tape.

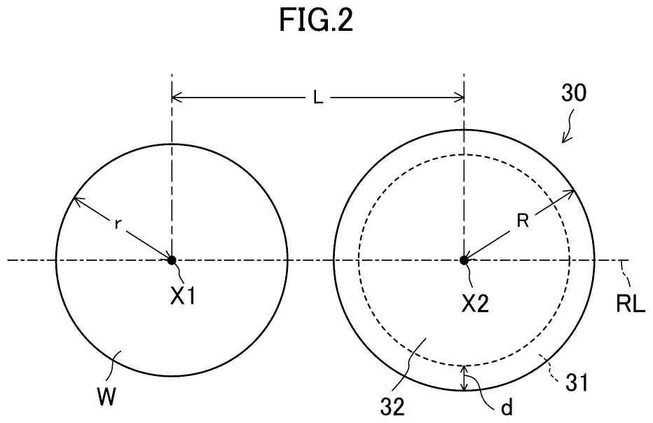

The table 20 is a rotary table having the rotative mount 21, and the base 22 includes a first motor 24 built therein to rotate the mount 21. The first motor 24 has a rotation shaft extending in the column 23. Thus, when the first motor 24 is driven, the mount 21 is rotated about the rotation shaft of the first motor 24, while the column 23 is not rotated. Although not shown, the mount 21 is provided with a guide for mounting the wafer W so that a central axis X1 of the wafer W (see FIG. 2, hereinafter referred to as a first central axis X1) is coaxial with the rotation shaft of the first motor 24. Thus, when the mount 21 is rotated, the wafer W is rotated about the first central axis X1. The first motor 24 corresponds to a first rotator that rotates the wafer W about the central axis X1. The first motor 24 may rotate the mount 21 together with the column 23.

The column 23 of the table 20 is provided with a first power feeder 25 that supplies electric charges to the wafer W. The first power feeder 25 is provided on part of the column 23 outside the tank body 11.

As shown in FIGS. 1 and 2, the machining electrode 30 has a circular shape in plan view, specifically, a bottomed cylindrical shape that is open toward the wafer W (downward in this example). The machining electrode 30 has an outer radius R larger than a radius r of the wafer W. A cylindrical portion 31 of the machining electrode 30 is a cylinder having a width d, and causes discharge between the cylindrical portion 31 and the wafer W.

The machining electrode 30 is held by a holder 40 via a shaft 41. The shaft 41 is connected to a center portion of a bottom 32 of the machining electrode 30. A second motor 42 that rotates the machining electrode 30 is built in the holder 40. The machining electrode 30 is connected to the shaft 41 so that its central axis X2 (corresponding to a cylinder axis, hereinafter referred to as a second central axis X2) is coaxial with a rotation shaft of the second motor 42. Thus, when the second motor 42 is driven, the machining electrode 30 is rotated about the second central axis X2. The second motor 42 corresponds to a second rotator that rotates the machining electrode 30 about the central axis X2.

The holder 40 is configured to be movable in the horizontal direction. Although not shown, a rail supporting the holder 40 and extending in the left-right direction is provided on a ceiling of the housing 2, and the holder 40 is movable in the left-right direction along the rail. The holder 40 can be moved in the left-right direction by any known method, for example, by using a rack and pinion mechanism or a servo motor.

The movement direction of the holder 40 is a direction along the radial direction of the wafer W, as shown in FIG. 2. Thus, the center of the wafer W is located on a straight line RL along a path drawn by the center of the machining electrode 30 when the holder 40 moves.

The holder 40 is configured to move the machining electrode 30 up and down by extending and contracting the shaft 41 in the up-down direction. Specifically, the holder 40 is configured to lower the machining electrode 30 when the shaft 41 is extended and raise the machining electrode 30 when the shaft 41 is contracted. The shaft 41 may be extended and contracted by any known method, for example, by using a servo motor.

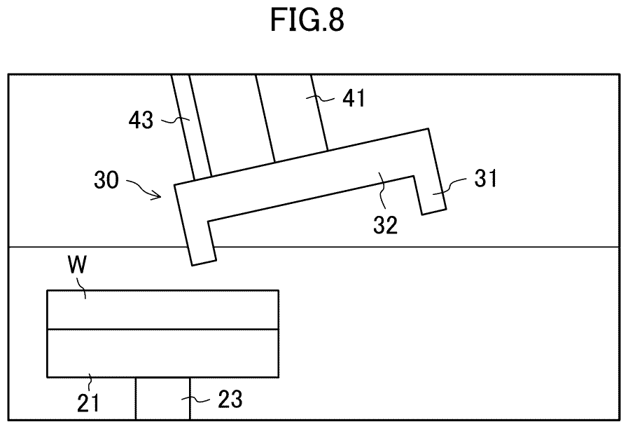

The holder 40 has a mechanism for tilting the shaft 41 with respect to the vertical direction. When the shaft 41 is tilted, the machining electrode 30 is also tilted with respect to the horizontal direction (see FIG. 8). Any known method can be used to tilt the shaft 41. When the shaft 41 is tilted, the second motor 42 is also tilted. That is, when the shaft 41 is tilted, the rotation shaft of the second motor 42 is also tilted by the same amount as the shaft 41.

The holder 40 is provided with a second power feeder 43 for feeding electric charges to the machining electrode 30. A lower end of the second power feeder 43 is in contact with the bottom 32 of the machining electrode 30, and the second power feeder 43 feeds the electric charges to the machining electrode 30 via the contact portion. Thus, although the machining electrode 30 is rotated, the second power feeder 43 is not rotated and feeds the electric charges. The second power feeder 43 may be configured to be in contact with the shaft 41.

The surface treatment device 1 includes a controller 50 that operates each component to perform the surface treatment of the wafer W. The controller 50 is electrically connected to the first motor 24, the first power feeder 25, the second motor 42, and the second power feeder 43. The controller 50 is also electrically connected to a mechanism for moving the holder 40 in the left-right direction (hereinafter referred to as a horizontal movement mechanism), a mechanism for extending and contracting the shaft 41 (hereinafter referred to as an extension and contraction mechanism), and a mechanism for tilting the shaft 41 (hereinafter referred to as a tilting mechanism).

### (Electrical Discharge Machining)

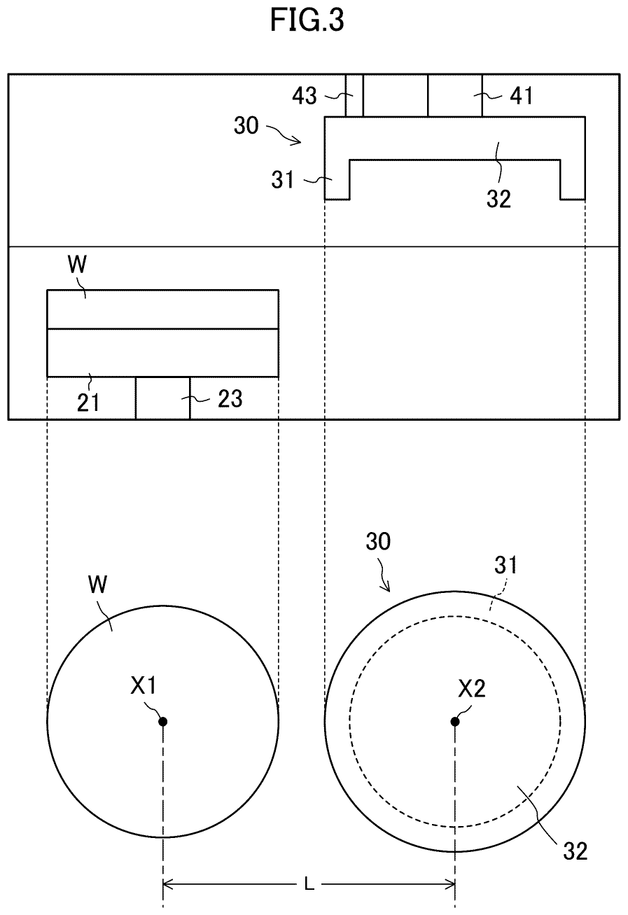

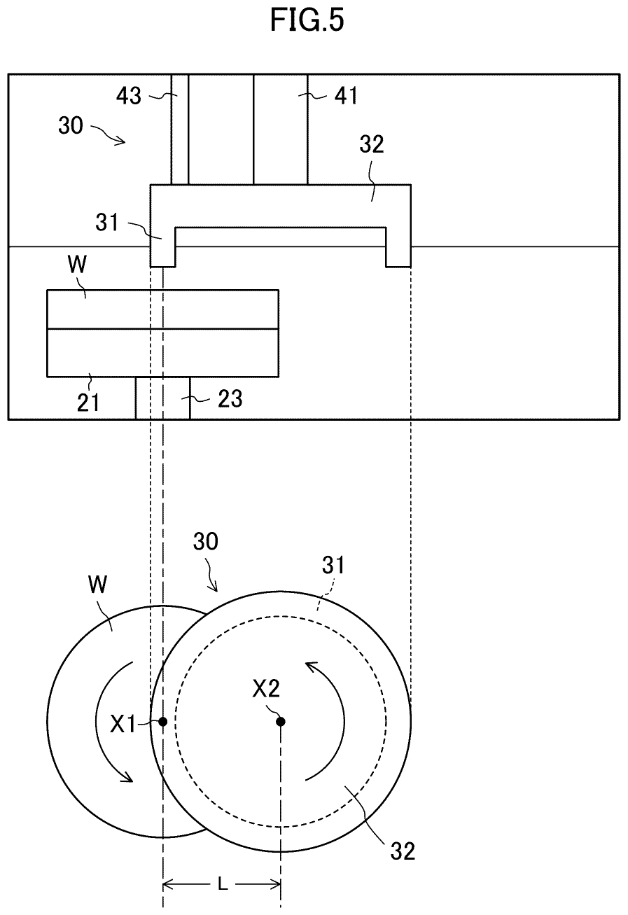

Next, a method of surface treatment of the wafer W by the surface treatment device 1 will be described in detail with reference to FIGS. 3 to 7. In FIGS. 3 to 7, a side view of the surface treatment device is shown in an upper part, and a top view (plan view) of the surface treatment device is shown in a lower part. In the following description, “the wafer W and the machining electrode 30 overlap each other” means that the wafer W and the machining electrode 30 overlap each other in plan view.

FIG. 3 shows the wafer W held on the table 20. At this moment, the machining electrode 30 is in the initial position. In this state, the wafer W and the machining electrode 30 do not overlap each other in the up-down direction, and a distance L between the central axis of the wafer W and the central axis of the machining electrode 30 is larger than the sum of the outer radius R of the machining electrode 30 and the radius r of the wafer W.

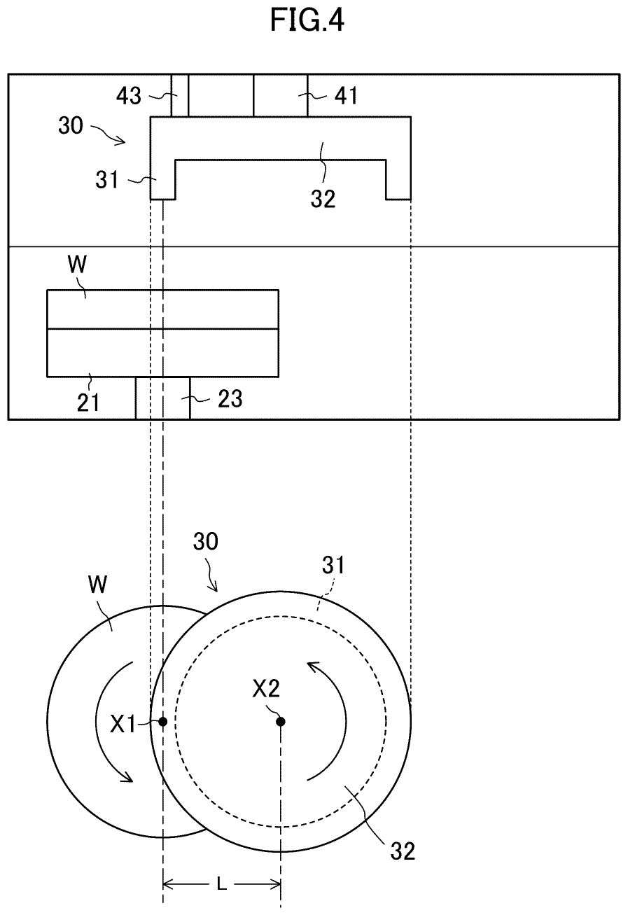

Then, the controller 50 causes the horizontal movement mechanism to move the holder 40 from the state shown in FIG. 3 so that the machining electrode 30 moves radially inward of the wafer W (to the left in this example). As shown in FIG. 4, the controller 50 positions the machining electrode 30 so that the cylindrical portion 31 of the machining electrode 30 is located on the first central axis X1 of the wafer W. More specifically, the controller 50 moves and positions the machining electrode 30 so that the midpoint of the width of the cylindrical portion 31 is located on the first central axis X1. In this state, the distance L between the central axes meets

$$L = R - d / 2$$

Positioning the machining electrode 30 in this manner allows the wafer W and the machining electrode 30 to partially overlap each other.

The controller 50 then operates the first motor 24 and the second motor 42 to rotate the wafer W about the first central axis X1 and rotate the machining electrode 30 about the second central axis X2. The wafer W rotates at 300 rpm at the maximum, and the machining electrode 30 rotates at 2300 rpm at the maximum. The number of rotations of the machining electrode 30 is controlled not to be an integer multiple of the number of rotations of the wafer W. Specifically, the number of rotations of the machining electrode 30 is controlled to be an irrational multiple, such as √2 times the number of rotations of the wafer W. As shown in FIG. 4, the wafer W and the machining electrode 30 rotate in the same direction. Thus, in a region where the wafer W and the machining electrode 30 overlap each other, the machining electrode 30 and the wafer W move in opposite directions.

Next, the controller 50 extends the shaft 41, using the extension and contraction mechanism, from the state shown in FIG. 4 to lower the machining electrode 30 to be close to the wafer W. When the distance between the wafer W and the machining electrode 30 in the up-down direction becomes equal to or less than a predetermined distance, the controller 50 operates the first power feeder 25 and the second power feeder 43 to start electrical discharge machining. The discharge voltage is about 50 V to about 300 V. The predetermined distance is set so that at least the cylindrical portion 31 of the machining electrode 30 is immersed in the treatment fluid. The controller 50 operates the first power feeder 25 and the second power feeder 43 so that pulsed discharge occurs between the wafer W and the machining electrode 30. The wafer W and the machining electrode 30 partially overlap each other, and thus the discharge region is limited to the overlapping region.

The polarity of the electrical discharge machining performed by the surface treatment device 1 can be either a positive polarity in which the wafer W serves as a positive electrode and the machining electrode 30 as a negative electrode or a reverse polarity in which the wafer W serves as a negative electrode and the machining electrode 30 as a positive electrode. In particular, the polarity of the electrical discharge machining is preferably changed as appropriate in accordance with the purpose of machining the wafer W. For example, when the machining speed is a priority, the positive polarity is selected for the electrical discharge machining. When the surface roughness of the wafer is a priority, the reverse polarity is selected for the electrical discharge machining. The polarity of the electrical discharge machining may be changed as appropriate in a period from the start to the end of the electrical discharge machining. The polarity of the electrical discharge machining may be changed as appropriate in accordance with the material of the workpiece. The polarity of the electrical discharge machining may be appropriately selected by an operator for each machining, or may be automatically selected by the controller 50.

Then, the controller 50 causes the horizontal movement mechanism to reciprocate the machining electrode 30 along the radial direction of the wafer W, while keeping the first power feeder 25 and the second power feeder 43 operated, that is, while causing the electrical discharge between the wafer W and the machining electrode 30. The range of the reciprocating movement of the machining electrode 30 is defined by the distance L between the center axes that meets

$$R - d < L < r + R$$

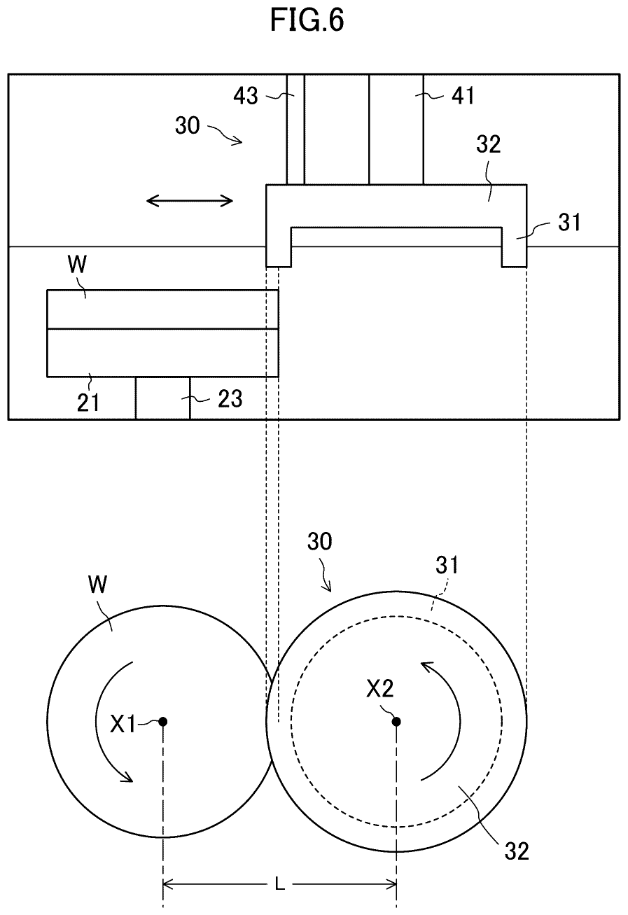

Specifically, as shown in FIG. 6, the controller 50 causes the machining electrode 30 to reciprocate between a treatment start position and a position where the midpoint of the width of the cylindrical portion 31 is located above the outer peripheral edge of the wafer W, that is, a position where the distance L between the center axes meets

$$L = r + R - d / 2$$

Specifically, the moving range of the machining electrode 30 is set so that the distance L between the center axes meets

$$R - d / 2 \leq L \leq r + R - d / 2$$

The controller 50 gradually reduces the distance between the wafer W and the machining electrode 30 in the up-down direction within a range where the wafer W and the machining electrode 30 do not make contact with each other. The controller 50 controls the speed of the horizontal movement of the machining electrode 30 or stops the horizontal movement of the machining electrode 30 in accordance with a desired surface shape. For example, if the desired surface shape is a convex shape, the horizontal movement of the machining electrode 30 is slowed or stopped when the cylindrical portion 31 of the machining electrode 30 overlaps only the peripheral portion of the wafer W so that the peripheral portion of the wafer W is machined more than the center portion.

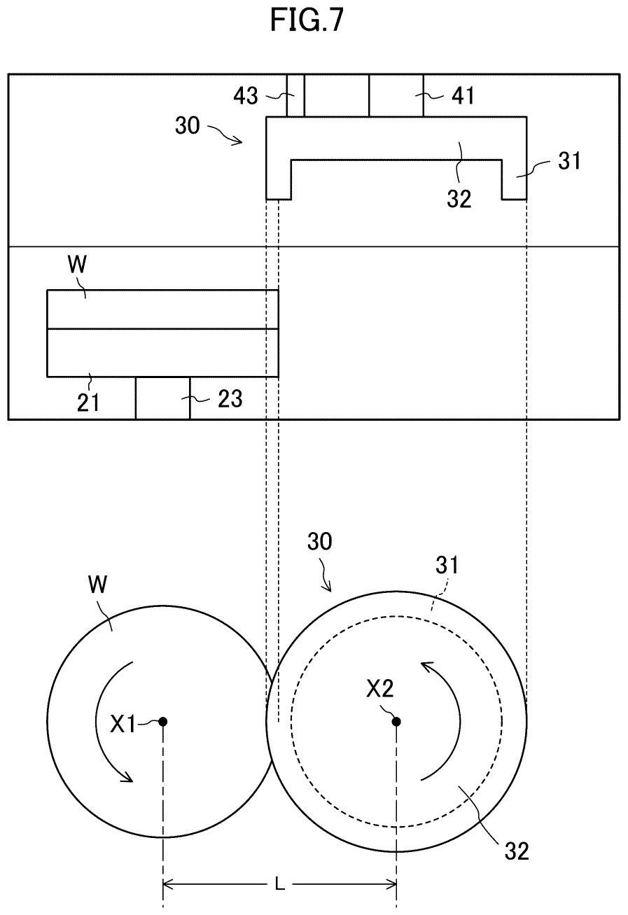

When the wafer W is machined into a desired surface shape, the controller 50 stops the first power feeder 25 and the second power feeder 43. Thereafter, as shown in FIG. 7, the controller 50 contracts the shaft 41 by the extension and contraction mechanism and raises the machining electrode 30 to be away from the wafer W. After stopping the rotation of the wafer W and the machining electrode 30, the controller 50 moves the machining electrode 30 to the initial position shown in FIG. 3.

In this way, the surface treatment of the wafer W by the electrical discharge machining is completed. The surface-treated wafer W held on the mount 21 is released and then collected by the operator.

In the first embodiment, the machining electrode 30 is circular in plan view, has the outer diameter equal to or larger than the outer diameter of the wafer W, and is positioned above the wafer W so that the machining electrode 30 partially overlaps the wafer W in plan view. The wafer W is rotated about the first central axis X1; the machining electrode 30 is rotated about the second central axis X2; and the discharge is caused between the machining electrode 30 and the wafer W with both the wafer W and the machining electrode 30 being rotated. Since the discharge is performed with the wafer W and the machining electrode 30 partially overlapping each other, the discharge region is limited. On the other hand, since the wafer W is rotated about the first central axis X1, every part of the surface of the wafer W comes directly below the machining electrode 30 at least once. This allows the electrical discharge machining of the entire surface of the wafer W while limiting the discharge region, reducing locally concentrated machining due to the surface state of the wafer W. The machining electrode 30 itself is also rotated about the second central axis X2, reducing the progress of local wear. This can reduce machining irregularities due to wear conditions of the machining electrode 30. Thus, unintended machining irregularities can be reduced, and the surface shape of the wafer W can be easily machined into a desired shape.

In the first embodiment, the machining electrode 30 has a cylindrical shape that is open toward the wafer W. The electrical discharge machining of the surface of the wafer W can be performed with the discharge region further limited. With the wafer W being rotated, the entire surface of the wafer W can be machined although the machining electrode 30 is cylindrical. This can reduce the influence of the surface state of the wafer W more effectively, and can reduce unintended machining irregularities more effectively.

In the first embodiment, the machining electrode 30 is moved in the horizontal direction during the electrical discharge machining. This can control time for machining the center portion and the peripheral portion of the wafer W according to a desired surface shape. Further, the cylindrical portion 31 of the machining electrode 30 can face any part of the surface of the wafer W. This can reduce unintended machining irregularities on one hand, while allowing intentionally localized machining according to the desired surface shape on the other.

In the first embodiment, in particular, the moving range of the machining electrode 30 is set so that the distance L between the center axes meets

$$R - d / 2 \leq L \leq r + R - d / 2$$

Thus, a region where the wafer W and the machining electrode 30 overlap each other can be more limited, allowing suitable machining of the entire wafer W. This can reduce the influence of the surface state of the wafer W and the locally concentrated wear of the machining electrode 30 more effectively.

In the first embodiment, the wafer W and the machining electrode 30 rotate in the same direction. Thus, in the region where the wafer W and the machining electrode 30 overlap each other, the moving directions of the machining electrode 30 and the wafer W can be as different as possible. This can reduce variations in machining time more effectively, and can reduce unintended machining irregularities more effectively.

In the first embodiment, the number of rotations of the machining electrode 30 is controlled not to be an integer multiple of the number of rotations of the wafer W. If the number of rotations of the machining electrode 30 is an integer multiple of the number of rotations of the wafer W, the cylindrical portion 31 of the machining electrode 30 regularly faces a certain part of the surface of the wafer W, and machining irregularities may occur. If the number of rotations of the machining electrode 30 is controlled not to be an integer multiple of the number of rotations of the wafer W, the cylindrical portion 31 of the machining electrode 30 faces different parts of the surface of the wafer W at random, reducing unintended machining irregularities more effectively.

FIG. 8 shows another use of the surface treatment device 1 of the first embodiment. In the surface treatment device 1, the tilting mechanism tilts the shaft 41 to cause the machining electrode 30 to tilt as shown in FIG. 8, so that the discharge region is more limited. This can make fine adjustment of the surface shape of the wafer W, allowing easy machining of the surface of the wafer W into a desired shape.

### (Machining of SiC Seed Crystal)

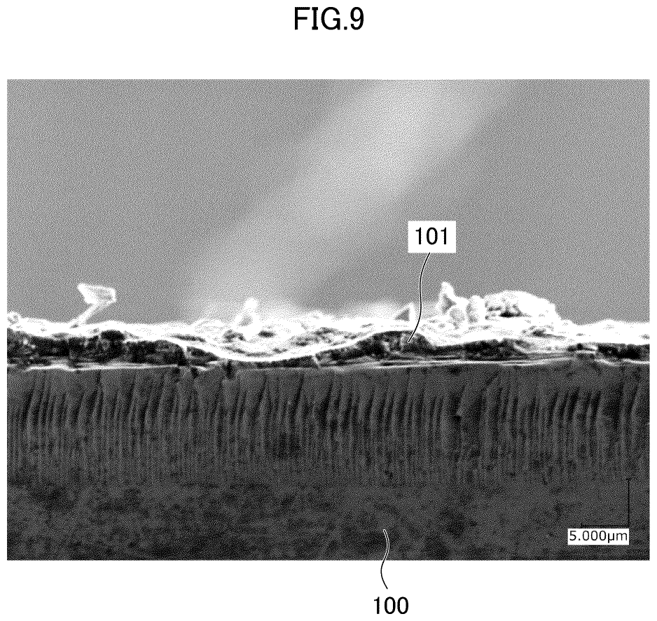

FIG. 9 shows a surface of a seed crystal of SiC as a workpiece (hereinafter simply referred to as a seed crystal 100), the surface of which has been subjected to the electrical discharge machining by the surface treatment device 1 of the first embodiment. The seed crystal 100 has a disc shape with a thickness ranging from 0.1 mm to 10 mm. The seed crystal 100 can be manufactured by, for example, slicing a SiC single crystal with a wire saw.

As can be seen from FIG. 9, a modified surface layer (hereinafter referred to as a modified layer 101) is formed on the surface of the seed crystal 100 after the electrical discharge machining is performed. The modified layer 101 is a layer containing other substances than SiC such as carbon and SiO₂. The electrical discharge machining by the surface treatment device 1 forms the modified layer 101 in a thickness of about 0.1 μm to about 10 μm.

As described above, the surface treatment performed by the surface treatment device 1 of the present embodiment can provide the modified layer 101 having appropriate surface roughness while reducing machining irregularities. The modified layer 101 formed in this manner allows the seed crystal 100 to be bonded to a mount with improved adhesion, and allows appropriate progress of the subsequent crystal growth.

### Second Embodiment

A second embodiment will be described in detail below with reference to the drawings. In the following description, the same components as those of the first embodiment will be denoted by the same reference numerals, and will not be described in detail.

A surface treatment device 201 of the second embodiment is different from that of the first embodiment in that the base 22 has no motor. In the second embodiment, a nozzle 260 that supplies the treatment fluid into the treatment tank 10 rotates the mount 21 instead of the motor to rotate the wafer W. The machining electrode 30 is rotated by the second motor 42 in the same manner as in the above-described first embodiment.

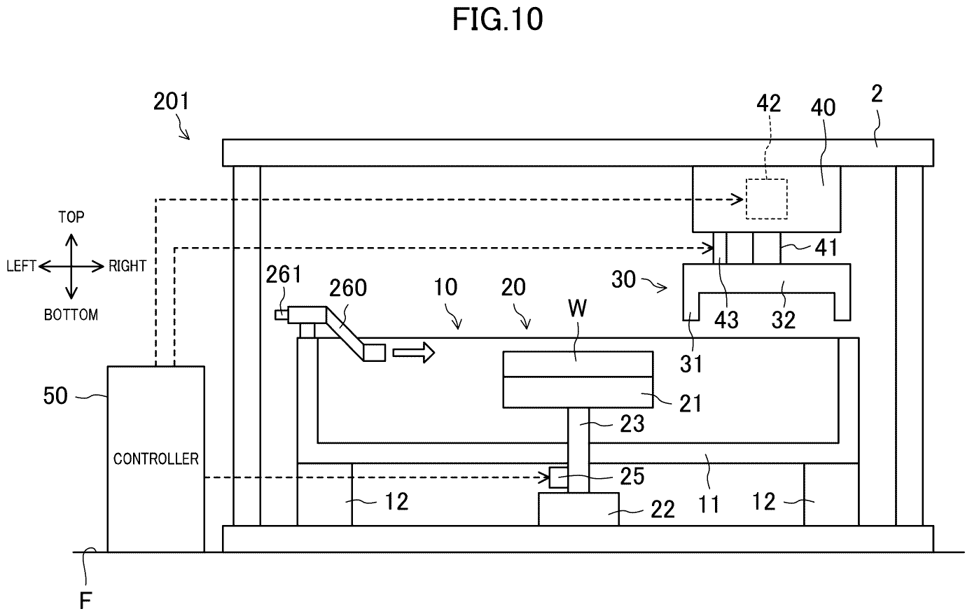

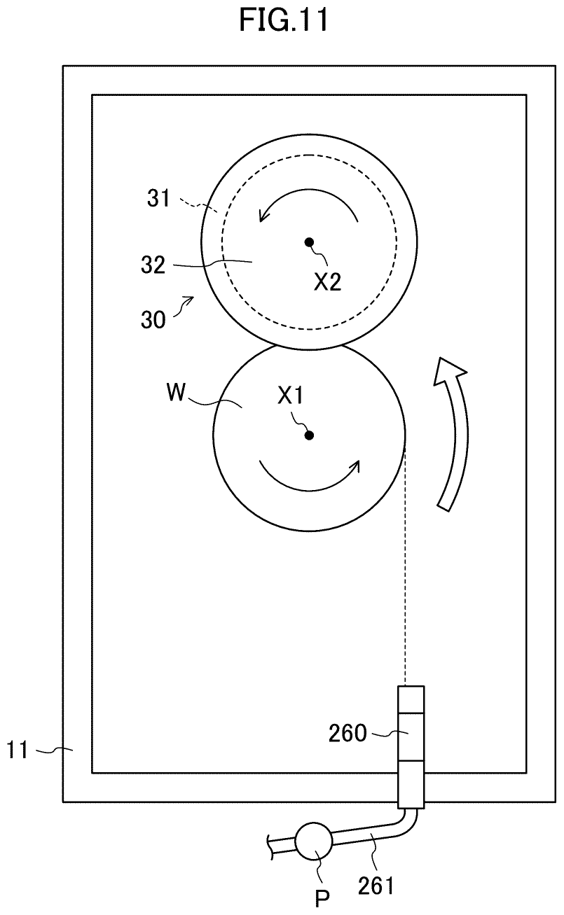

Specifically, as shown in FIGS. 10 and 11, the nozzle 260 for supplying the treatment fluid to the treatment tank 10 is provided to face the machining electrode 30 across the table 20. The nozzle 260 is connected to a pump P via a hose 261, and the treatment fluid is pumped from the pump P. The treatment tank 10 is provided with a discharge pipe (not shown) for discharging an excess of the treatment fluid (that is, the treatment fluid that cannot be contained in the tank) that occurs due to the treatment fluid supplied by the nozzle 260. The treatment fluid discharged from the discharge pipe is sent to the pump P and is supplied again from the nozzle 260 to the treatment tank 10. The pump P is electrically connected to the controller 50 and is configured to be able to adjust the flow rate of the treatment fluid to be pumped, that is, supply pressure.

As shown in FIG. 11, the nozzle 260 is positioned on an extension line of a tangent of the wafer W. Thus, a force caused by the flow of the discharged treatment fluid is inputted to the wafer W in the tangential direction, rotating the wafer W. The controller 50 controls the rotational speed by controlling the supply pressure of the treatment fluid from the pump P to the nozzle 260 and controlling the force of the treatment fluid supplied from the nozzle 260 into the tank.

The second embodiment is the same as the first embodiment except that the device for rotating the wafer W is changed. That is, the machining electrode 30 causes electrical discharge to the wafer W while partially overlapping the wafer W. More specifically, the machining electrode 30 causes electrical discharge to the wafer W while reciprocating between a position where the distance L between the central axes meets

$$L = R - d / 2$$

and the position where the distance L between the central axes meets

$$L = r + R - d / 2$$

Also in such a configuration, the entire surface of the wafer W can be machined by electrical discharge machining by rotating the wafer W about the first central axis X1 while limiting the discharge region. This can reduce locally concentrated machining due to the surface state of the wafer W. The machining electrode 30 itself is also rotated about the second central axis X2, thereby making it possible to reduce the progress of local wear. This can reduce machining irregularities due to wear conditions of the machining electrode 30. Thus, unintended machining irregularities can be reduced, and the surface shape of the wafer W can be easily machined into a desired shape.

### Other Embodiments

The technique disclosed herein is not limited to the above-described embodiments, and can be substituted without departing from the scope of the claims.

For example, the machining electrode 30 of the first and second embodiments is configured to be movable in the horizontal direction. The present disclosure is not limited to this configuration, and the relative positions of the machining electrode 30 and the workpiece may be fixed. In such a case, the machining electrode 30 is arranged so that the cylindrical portion 31 is positioned on the first central axis X1 of the workpiece. It is thus possible to machine the entire surface of the workpiece by electrical discharge machining by rotating the workpiece about the first central axis X1.

In the first and second embodiments, the machining electrode 30 is moved in the horizontal direction to change the relative positions of the workpiece and the machining electrode 30. The present disclosure is not limited to this configuration, and the table 20 may be moved in the horizontal direction together with the workpiece to change the relative positions of the workpiece and the machining electrode 30. In this case, it is preferable to place the entire table 20 inside the treatment tank 10 and provide a mechanism for moving the base 22 in the horizontal direction. The first power feeder 25 is preferably built in the base 22.

In the first and second embodiments, the machining electrode 30 reciprocates between the position where the distance L between the central axes meets

$$L = R - d / 2$$

and the position where the distance L between the central axes meets

$$L = r + R - d / 2$$

The present disclosure is not limited to this configuration, and the machining electrode 30 may reciprocate in any range according to the desired surface shape as long as the distance L between the central axes meets

$$R - d < L < r + R$$

and a condition that the cylindrical portion 31 of the machining electrode 30 is positioned on the first central axis X1 at least once in a single reciprocation is satisfied.

In the first and second embodiments, the machining electrode 30 has a bottomed cylindrical shape. The present disclosure is not limited to this configuration, and the machining electrode 30 may have a disc shape or a cylindrical shape that is open on both sides toward the workpiece and the holder.

The above-described embodiments are merely examples, and the scope of the present disclosure should not be interpreted in a limited manner. The scope of the present disclosure is defined by the appended claims, and all modifications and changes that fall within the range of equivalency of the claims are intended to be incorporated therein.

### INDUSTRIAL APPLICABILITY

The technique disclosed herein is useful for performing electrical discharge machining on a surface of a disc-shaped workpiece using a machining electrode.

### DESCRIPTION OF REFERENCE CHARACTERS

1 Surface Treatment Device
20 Table
24 First Motor (First Rotator)
30 Machining Electrode
31 Cylindrical Portion
42 Second Motor (Second Rotator)
50 Controller
100 Seed Crystal (Workpiece)
W Wafer (Workpiece)
X1 First Central Axis (Central Axis of Workpiece)
X2 Second Central Axis (Central Axis of Machining Electrode)

1. A surface treatment method for performing electrical discharge machining on a surface of a disc-shaped workpiece using a machining electrode,
the machining electrode having a circular shape in plan view and an outer diameter equal to or larger than an outer diameter of the workpiece, the method comprising:
positioning the machining electrode above the workpiece so that the workpiece and the machining electrode partially overlap each other in plan view;
rotating the workpiece about a central axis of the workpiece;
rotating the machining electrode about a central axis of the machining electrode; and
discharging between the machining electrode and the workpiece, with both the workpiece and the machining electrode being rotated.

2. The surface treatment method of claim 1, wherein
the machining electrode has a cylindrical shape that is open toward the workpiece.

3. The surface treatment method of claim 1, further comprising:
moving at least one of the workpiece or the machining electrode in a horizontal direction during the discharging.

4. The surface treatment method of claim 3, wherein
the machining electrode has a cylindrical shape that is open toward the workpiece, and
the moving includes moving the at least one of the workpiece or the machining electrode in the horizontal direction in a range where a distance L between the central axis of the workpiece and the central axis of the machining electrode meets
$$R - d < L < r + R$$
where r represents a radius of the surface of the workpiece, R represents an outer radius of the machining electrode, and d represents a width of a cylindrical portion of the machining electrode (d<r).

5. The surface treatment method of claim 4, wherein
a direction of rotation of the workpiece during the rotating and a direction of rotation of the machining electrode during the rotating are the same.

6. A surface treatment device configured to perform electrical discharge machining on a surface of a disc-shaped workpiece, the device comprising:
a table on which the workpiece is placed and held;
a machining electrode having a circular shape in plan view and an outer diameter equal to or larger than an outer diameter of the workpiece;
a first rotator configured to rotate the workpiece about a central axis of the workpiece;
a second rotator configured to rotate the machining electrode about a central axis of the machining electrode; and
a controller electrically connected to the machining electrode, the first rotator, and the second rotator, wherein
the controller causes the first rotator to rotate the workpiece and causes the second rotator to rotate the machining electrode, with the workpiece and the machining electrode partially overlapping each other in plan view to perform the electrical discharge machining.

7. The surface treatment device of claim 6, wherein
the machining electrode has a cylindrical shape that is open toward the workpiece.

8. The surface treatment device of claim 6, wherein
at least one of the table or the machining electrode is configured to be movable in a horizontal direction, and
the controller is configured to be able to perform the electrical discharge machining while moving at least one of the table or the machining electrode in the horizontal direction.

9. The surface treatment method of claim 5, wherein
a number of rotations of the machining electrode during the rotating is not an integer multiple of a number of rotations of the workpiece during the rotating.

10. The surface treatment device of claim 6, wherein
the controller controls the first rotator and the second rotator so that a number of rotations of the machining electrode is not an integer multiple of a number of rotations of the workpiece.
